(19) United States
(12) Patent Application Publication
(10) Pub. No.: US 2025/0370053 A1
(43) Pub. Date: Dec. 4, 2025

(54) DETECTION CIRCUIT AND METHOD FOR DETECTING INTERNAL RESISTANCE OF BATTERY UNIT

(71) Applicant: Joulwatt Technology Co., Ltd., Hangzhou (CN)

(72) Inventor: Hongxia DU, Hangzhou (CN)

(21) Appl. No.: 19/221,262

(22) Filed: May 28, 2025

(30) Foreign Application Priority Data
May 31, 2024 (CN) 202410703389.X

(51) Int. Cl. G01R 31/389; G01R 31/3842; H02J 7/00

(52) U.S. Cl. CPC G01R 31/389; G01R 31/3842; H02J 7/0047; H02J 7/00712

(57) ABSTRACT

Disclosed is a detection circuit and a method for detecting an internal resistance of a battery unit. By controlling an operating frequency of a first switch, a disturbance current of a certain frequency is generated, causing a voltage disturbance. A first analog-to-digital converter converts the voltage disturbance into a first digital signal. The internal resistance of a corresponding sub-battery is detected based on the first digital signal, and a discharge current or a second digital signal converted from a current sampling signal of the discharge current. By sending a difference between a battery voltage and a reference voltage to the first analog-to-digital converter for conversion, compared with directly sending a battery voltage, the voltage range to be quantified by the first analog-to-digital converter is smaller, improving resolution, reducing quantization error, enhancing detection accuracy, eliminating a need for using a DC-blocking filter capacitor, saving space, facilitating integration and miniaturization.

### CROSS-REFERENCE TO PRIOR APPLICATIONS

The present application claims priority to Chinese Patent Application No. 202410703389.X, filed on May 31, 2024, entitled “DETECTION CIRCUIT AND METHOD FOR DETECTING INTERNAL RESISTANCE OF BATTERY UNIT”, the entire content of which is incorporated herein by reference, including the specification, claims, drawings, and abstract.

### TECHNICAL FIELD

The present disclosure relates to a field of battery technology, in particular to a detection circuit and a method for detecting an internal resistance of a battery unit.

### BACKGROUND

In the prior art, batteries are often used to supply power for electronic devices, and it is usually necessary to measure an internal resistance of the battery. The internal resistance of the battery is an important parameter for evaluating the lifetime and health status of the battery. In the prior art, methods for measuring battery internal resistance often require a DC-blocking filter capacitor. Through this capacitor, the disturbance amount of the battery voltage can be obtained, and based on a ratio of this voltage disturbance amount to the discharge current, a corresponding battery internal resistance can be determined. However, a frequency band for measuring battery internal resistance is generally wide, and the DC-blocking filter capacitor is usually set to be large, which results in a large occupied area, making it unfavorable for miniaturization and integration. Therefore, it is necessary to improve the existing technology to solve the problems existing in the prior art.

### SUMMARY

To solve the above technical problems, the present disclosure provides a detection circuit and a method for detecting an internal resistance of a battery unit.

According to a first aspect of the present disclosure, a battery unit internal resistance detection circuit is provided, wherein the battery unit comprises at least one sub-battery connected in series, where N represents a quantity of the at least one sub-battery and is a natural number greater than or equal to 1; wherein the detection circuit comprises:
first to fourth ports, wherein a positive terminal of the battery unit is coupled to the first port, and a negative terminal of the battery unit is coupled to the second port; the third port is coupled to a positive terminal of one of the at least one sub-battery, and the fourth port is coupled to a negative terminal of the one of the at least one sub-battery;
a discharge current generation circuit and a first switch, wherein the discharge current generation circuit and the first switch are serially arranged in a branch between the first port and the second port, the discharge current generation circuit is used to generate a discharge current, and by controlling an operating frequency of the first switch, a current disturbance occurs in the battery unit;
a first analog-to-digital converter, which, based on the current disturbance, converts a difference between a voltage at the third port and a reference voltage into a first digital signal, the reference voltage being generated by a reference voltage generation circuit;
a logic control circuit, wherein the logic control circuit is configured to control the operating frequency of the first switch, and obtain an internal resistance of the sub-battery coupled between the third port and the fourth port in accordance with the first digital signal, and the discharge current or a second digital signal converted from a current sampling signal of the discharge current; or, the logic control circuit is configured to send the first digital signal, and the discharge current signal or the second digital signal converted from the current sampling signal of the discharge current, to a processor which is configured to process the signals to obtain the internal resistance of the sub-battery coupled between the third port and the fourth port.

Optionally, the detection circuit further comprises a current sampling circuit, used to sample the discharge current to obtain the current sampling signal, and the first analog-to-digital converter is further used to convert the current sampling signal into the second digital signal.

Optionally, the reference voltage generation circuit is a digital-to-analog converter, which is used to convert a received digital signal into the reference voltage.

Optionally, the received digital signal is either a digital signal output by the logic control circuit, or a digital signal which is converted by the first analog-to-digital converter from a maximum voltage detected at the third port when the first switch is operated in off state.

Optionally, when the logic control circuit controls the first switch to operate at a predetermined frequency, the reference voltage is an average value of a voltage at the third port.

Optionally, the reference voltage generation circuit comprises a second analog-to-digital converter and a digital-to-analog converter; an input terminal of the second analog-to-digital converter is coupled to the third port, and when the logic control circuit controls the first switch to operate at the predetermined frequency: the second analog-to-digital converter performs analog-to-digital conversion and averaging operation on the voltage at the third port in at least one consecutive switching cycle and then outputs a third digital signal; or the second analog-to-digital converter outputs a third digital signal every time when a timing reaches a predetermined timing period, wherein the second analog-to-digital converter performs analog-to-digital conversion and averaging operation on the voltage at the third port within the predetermined timing period and then outputs the third digital signal; and the digital-to-analog converter is configured to convert the third digital signal into the reference voltage.

Optionally, the detection circuit further comprises a second switch and a third switch; the second switch is coupled in a branch between the reference voltage generation circuit and the first analog-to-digital converter; the third switch is coupled in a branch between the third port and the first analog-to-digital converter; the logic control circuit is configured to control on and off states of the second switch and the third switch;
when the second switch and the third switch are operated in on state, the first analog-to-digital converter converts the difference between the voltage at the third port and the reference voltage into the first digital signal.

Optionally, the current sampling circuit is a resistor, which is serially connected in a branch where the discharge current generation circuit is located; the current sampling signal is obtained in accordance with a voltage across the resistor;
the detection circuit further comprises a fourth switch and a fifth switch; the fourth switch is coupled in a branch between a first end of the resistor and the first analog-to-digital converter; the fifth switch is coupled in a branch between a second end of the resistor and the first analog-to-digital converter; the logic control circuit is configured to control on and off states of the fourth switch and the fifth switch;
when the fourth switch and the fifth switch are operated in on state, the first analog-to-digital converter converts the current sampling signal into the second digital signal.

Optionally, when N is greater than 1, the detection circuit further comprises a multiplexer, which is coupled to positive and negative terminals of the N sub-batteries; the multiplexer is used to select and couple a positive terminal of the i-th sub-battery of the N sub-batteries with the third port in a time-sharing manner, and to couple a negative terminal of the i-th sub-battery with the fourth port, where 1≤i≤N.

Optionally, the voltage across the sub-battery that is coupled between the third port and the fourth port is obtained using a Kelvin connection approach.

Optionally, the detection circuit is integrated inside a single chip; or, components of the detection circuit, except for the processor, is integrated inside a single chip.

The present disclosure also provides a method for detecting an internal resistance of a battery unit, wherein the battery unit comprises at least one sub-battery connected in series, where N represents a quantity of the at least one sub-battery and is a natural number greater than or equal to 1; wherein the method comprises:
arranging a discharge current generation circuit and a first switch in series in a branch between a positive terminal and a negative terminal of the battery unit; controlling an operating frequency of the first switch, to allow a current disturbance to occur in the battery unit;
coupling a positive terminal of one of the at least one sub-battery to the third port, and coupling the fourth port to a negative terminal of the one of the at least one sub-battery; based on the current disturbance, converting a difference between a voltage at the third port and a reference voltage into a first digital signal through a first analog-to-digital converter;
in accordance with the first digital signal, and the discharge current or a second digital signal converted from a current sampling signal of the discharge current, obtaining an internal resistance of the sub-battery coupled between the third port and the fourth port; or, sending the first digital signal, and the discharge current signal or the second digital signal converted from the current sampling signal of the discharge current, to a processor which is configured to process the signals to obtain the internal resistance of the sub-battery coupled between the third port and the fourth port.

Optionally, the current sampling signal is obtained by sampling the discharge current, and is converted into the second digital signal by the first analog-to-digital converter.

Optionally, the reference voltage is obtained by conversion through a digital-to-analog converter, which is used to convert a received digital signal into the reference voltage.

Optionally, the received digital signal is either a digital signal output by the logic control circuit, or a digital signal converted by the first analog-to-digital converter from a maximum voltage at the third port when the first switch is operated in off state.

Optionally, when the logic control circuit controls the first switch to operate at a predetermined frequency, the reference voltage is an average value of a voltage at the third port.

Optionally, when N is greater than 1, positive and negative terminals of the N sub-batteries are coupled to a multiplexer; the multiplexer is used to select and couple a positive terminal of an i-th sub-battery of the N sub-batteries with the third port in a time-sharing manner, and to couple a negative terminal of the i-th sub-battery with the fourth port, where 1≤i≤N.

Optionally, the voltage across the sub-battery that is coupled between the third port and the fourth port is obtained using a Kelvin connection approach.

The present disclosure at least has following advantages:
the detection circuit and the method for detecting the internal resistance of the battery unit provided by the present disclosure, controls the operating frequency of the first switch through the logic control circuit, so that a disturbance current at a certain frequency occurs in the battery unit, thereby causing a certain disturbance on the voltage of the battery unit. The disturbance amount of the voltage (or the difference between the voltage at the third port and the reference voltage) is converted into the first digital signal by the first analog-to-digital converter, and the internal resistance of the corresponding sub-battery is detected based on the first digital signal and the discharge current. According to the present disclosure, by sending the difference between the voltage at the third port VBAT and the reference voltage VREF to the first analog-to-digital converter for conversion, compared to a solution which directly sends the voltage VBAT at the third port to the first analog-to-digital converter for conversion, the voltage range to be quantified by the first analog-to-digital converter is smaller, which can improve resolution, reduce quantization error, and enhance detection accuracy. Moreover, this approach avoids the use of a DC-blocking filter capacitor, saving space and facilitating integration and miniaturization.

Furthermore, a current sampling circuit can be arranged to sample a magnitude of the discharge current, and the current sampling signal is converted into the second digital signal by the first analog-to-digital converter. Based on the first digital signal and the second digital signal, the internal resistance of the corresponding sub-battery is detected. With the above setup, since both the first digital signal and the second digital signal are converted by the first analog-to-digital converter, gain errors caused by different analog-to-digital converters can be avoided, improving the accuracy of battery internal resistance detection. Moreover, under the same detection accuracy, the discharge current can be set to a reduced magnitude through the solution provided according to the present disclosure, thereby reducing system power consumption.

Furthermore, the reference voltage according to the present disclosure can be converted by a digital-to-analog converter, where the digital signal can be a digital signal output by the logic control circuit, or a digital signal converted by the first analog-to-digital converter from a maximum value of the voltage of the battery. The reference voltage can also be the average value of the voltage of the battery. That is, the magnitude of the reference voltage according to the present disclosure can be adjusted according to the corresponding digital signal, enhancing flexibility.

It should be noted that the above general description and the following detailed description are merely exemplary and explanatory and do not limit the present disclosure.

### BRIEF DESCRIPTION OF THE DRAWINGS

FIG. 1 shows a schematic diagram of a detection circuit for detecting an internal resistance of a battery unit according to an embodiment of the present disclosure;

FIG. 2 shows an operating waveform diagram of a detection circuit for detecting an internal resistance of a battery unit according to an embodiment of the present disclosure;

FIG. 3 shows a schematic diagram of a reference voltage generation circuit according to an embodiment of the present disclosure;

FIG. 4 shows a schematic diagram of a reference voltage generation circuit according to another embodiment of the present disclosure;

FIG. 5 shows a schematic diagram of a detection circuit for detecting an internal resistance of a battery unit according to another embodiment of the present disclosure;

FIG. 6 shows a schematic diagram of a detection circuit for detecting an internal resistance of a battery unit according to another embodiment of the present disclosure.

### DETAILED DESCRIPTION

To facilitate understanding of the present disclosure, a more comprehensive description of the present disclosure will be provided below with reference to the relevant drawings. The preferred embodiments of the present disclosure are given in the drawings. However, the present disclosure can be implemented in different forms and is not limited to the embodiments described herein. On the contrary, the provision of these embodiments is to make the disclosure of the present disclosure more thorough and comprehensive.

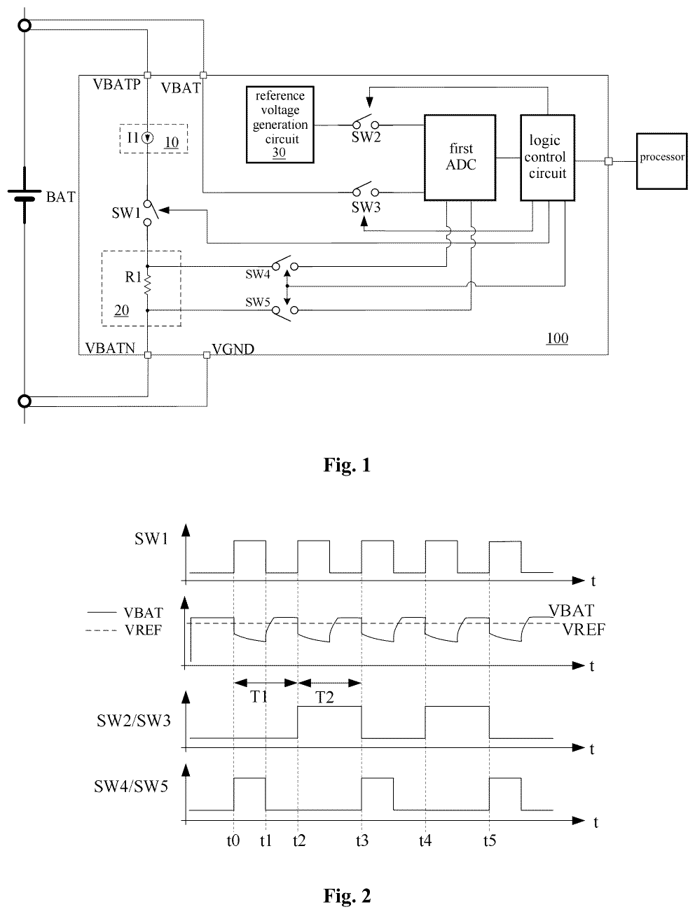

FIG. 1 shows a schematic diagram of a detection circuit for detecting an internal resistance of a battery unit provided according to an embodiment of the present disclosure, including a battery unit BAT, wherein the battery unit may include at least one sub-battery connected in series, where N represents a quantity of the at least one sub-battery and is a natural number greater than or equal to 1. In FIG. 1, N is illustrated as equal to 1 (i.e., the battery unit BAT contains one sub-battery). It should be noted that when N is equal to 1, the battery unit BAT may also represent multiple parallel-connected sub-batteries. The detection circuit further includes a discharge current generation circuit 10, a first switch SW1, a reference voltage generation circuit 30, a first analog-to-digital converter (ADC), and a logic control circuit. The detection circuit also has first to fourth ports, a positive terminal of the battery unit BAT is coupled to the first port VBATP, and a negative terminal of the battery unit BAT is coupled to the second port VBATN. The discharge current generation circuit 10 is arranged in a branch between the first port VBATP and the second port VBATN to generate a discharge current between the first port VBATP and the second port VBATN. The first switch SW1 is connected in series in the branch where the discharge current generation circuit 10 is located, and on and off states of the first switch SW1 are controlled by the logic control circuit, i.e., the logic control circuit is configured to control an operating frequency of the first switch. By controlling the on and off states of the first switch, current disturbance at a certain frequency can be generated on the battery unit BAT; this current disturbance will further cause a certain fluctuation on the voltage of the battery unit BAT. The positive terminal of the battery unit BAT is coupled to the third port VBAT, the negative terminal of the battery unit BAT is connected to the fourth port VGND, and the voltage of the battery unit BAT is detected through the third port VBAT. The first analog-to-digital converter is used to convert a difference between the voltage at the third port VBAT and the reference voltage VREF (this difference can represent the voltage fluctuation amount on the battery unit) into a first digital signal; wherein the reference voltage is generated by the reference voltage generation circuit 30. In the first embodiment of the present disclosure, the logic control circuit can obtain the internal resistance of the battery unit VBAT based on the first digital signal and the magnitude of the discharge current, or, as shown in FIG. 1, the detection circuit can also be equipped with a processor, which processes the first digital signal and the discharge current to obtain the internal resistance of the battery unit BAT. By sending the difference between the voltage at the third port VBAT and the reference voltage VREF to the first analog-to-digital converter for conversion, compared to a solution which directly sends the voltage at the third port VBAT to the first analog-to-digital converter for conversion, the voltage range to be quantified by the first analog-to-digital converter is smaller, which can improve resolution, reduce quantization error, and enhance detection accuracy. Moreover, this approach avoids the use of a DC-blocking filter capacitor, saving space and facilitating integration and miniaturization.

However, the solution as mentioned above directly uses the discharge current to calculate the internal resistance of the battery unit, and requires high accuracy on designing the discharge current. To address this issue, further, as shown in FIG. 1, according to the second embodiment of this document, the detection circuit is also equipped with a current sampling circuit 20, which is arranged in a branch where the discharge current generation circuit is located, used to sample the discharge current to obtain a current sampling signal, and the first analog-to-digital converter is further used to convert the current sampling signal into a second digital signal. In this embodiment, the logic control circuit can obtain an internal resistance of the battery unit VBAT based on the first digital signal and the second digital signal, or, as shown in FIG. 1, the detection circuit can also be equipped with a processor, and the logic control circuit is configured to send the first digital signal and the second digital signal to the processor, which processes the first digital signal and the second digital signal to obtain the internal resistance of the battery unit BAT. In this embodiment, the magnitude of the discharge current is also sampled through the current sampling circuit, a problem that the accuracy of detecting the internal resistance of the battery unit is low when the design accuracy of the discharge current is not high can be avoided, i.e., the detection accuracy of the battery unit can be improved; at the same time, both the first digital signal representing the voltage disturbance and the second digital signal representing the current sampling signal are converted by the first analog-to-digital converter, thus, when calculating the internal resistance of the battery unit based on these two digital signals, gain errors caused by using different analog-to-digital converters can be avoided, further improving the detection accuracy of the internal resistance of the battery unit. Of course, for applications with low requirements on the detection accuracy of the internal resistance of the battery unit, two analog-to-digital converters can also be arranged to perform analog-to-digital conversion on the corresponding voltage and the current sampling signal separately.

As shown in FIG. 1, the discharge current generation circuit 10 is represented by a current source I1, and the specific generation method performed by the current source I1 is not limited in the present disclosure. The resistor R1 can serve as the current sampling circuit 20, and the current sampling signal is obtained based on the voltage across the resistor R1. It should be noted that the current sampling signal in the present disclosure is not limited to a current signal and can also be a voltage signal; of course, other methods can also be used to sample the current. The resistor R1 is also connected in the branch where the discharge current generation circuit is located, and a fourth switch SW4 is arranged between the first end of the resistor R1 and the first analog-to-digital converter; a fifth switch SW5 is arranged between the second end of the resistor R1 and the first analog-to-digital converter, and the on and off states of the fourth switch and the fifth switch are controlled by the logic control circuit. The detection circuit further includes a second switch SW2 and a third switch SW3; the second switch SW2 is connected between the reference voltage generation circuit 30 and the first analog-to-digital converter; the third switch SW3 is connected between the third port VBAT and the first analog-to-digital converter; the on and off states of the second switch and the third switch are also controlled by the logic control circuit. It should be noted that the description of A being connected between B and C in the present disclosure is not limited to a situation where A is directly connected to B and C, but also includes a situation where a component other than A is connected between B and C. By controlling the on and off states of the first to fifth switches, the detection of the internal resistance of the battery unit can be realized.

FIG. 2 shows an operating waveform diagram of the detection circuit. In conjunction with FIG. 2, the principle of the detection circuit in this embodiment is further explained below. Before time to, the first switch SW1 is in off state. After time to, the logic control circuit controls the first switch SW1 to operate at a certain frequency (i.e., the first switch SW1 is turned on and off alternately). Between time t0 and time t1, the first switch is controlled to operate in on state, and between time t1 and time t2, the first switch is controlled to operate in off state. The time period between time t0 to time t2 is a switching cycle T, and so on; with the alternating on and off states of the first switch, a disturbance current at a certain frequency is generated on the battery unit BAT, causing the voltage VBAT on the battery unit BAT to change as shown in FIG. 2. In the first switching cycle T1, between time t0 and time t1, the logic control circuit controls the fourth switch SW4 and the fifth switch SW5 to operate in on state. At this time, the first analog-to-digital converter receives the voltage across the resistor R1 and converts the corresponding voltage value into the second digital signal, and the logic control circuit receives this second digital signal; the current flowing through the resistor R1 (i.e., the discharge current I1) is a ratio of this voltage to the resistor R1. In the embodiment shown in FIG. 1, this voltage value is used to represent a corresponding current sampling signal. Between time t1 and time t2, the fourth switch and the fifth switch are controlled to operate in off state. In the second switching cycle T2 (t2−t3), the logic control circuit controls the second switch SW2 and the third switch SW3 to operate in on state. At this time, the first analog-to-digital converter can receive the voltage VBAT across the battery unit and the reference voltage VREF, and convert the difference ΔV between these two voltages into a first digital signal, and the logic control circuit receives this first digital signal; the logic control circuit processes the first digital signal and the second digital signal to obtain the internal resistance of the battery unit, or, in some other embodiments, the logic control circuit can also send the first digital signal and the second digital signal to the processor, which performs corresponding processing operation to obtain the internal resistance of the battery unit. In another embodiment of this application, a corresponding division circuit can also be arranged before the first analog-to-digital converter to directly obtain the magnitude of the current flowing through the resistor R1, and the first analog-to-digital converter converts this current into the second digital signal. After time t3, the operating process corresponding to the first switching cycle and the second switching cycle can be repeated.

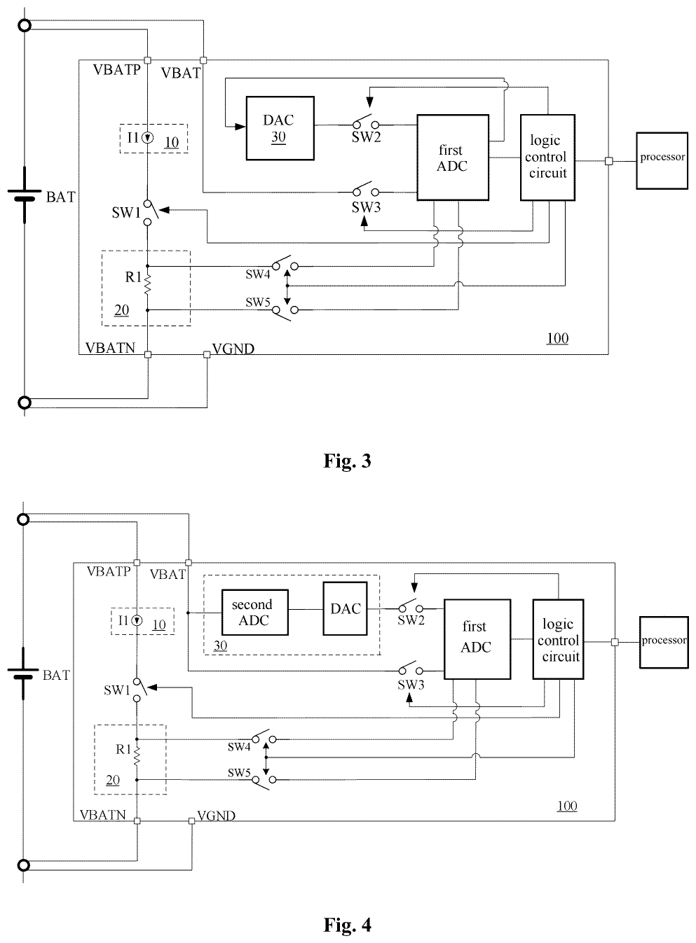

Furthermore, the reference voltage VREF can be generated by a digital-to-analog converter (DAC), which is used to convert the received digital signal into the reference voltage VREF. This digital signal can be provided from the logic control circuit or be generated by other means. For example, FIG. 3 shows an embodiment of a reference voltage generation circuit provided according to an embodiment of the present disclosure. Referring to FIG. 3, the digital signal of the digital-to-analog converter is generated by the first analog-to-digital converter. Specifically, when the first switch SW1 is operated in off state, the third switch SW3 can be turned on. At this time, a maximum value of the voltage VBAT across the battery unit is input to the first analog-to-digital converter, and is converted, by the first analog-to-digital converter, into a corresponding digital signal, which is input to the digital-to-analog converter; specifically, the maximum value of the voltage VBAT can be obtained by arranging a corresponding circuit, which is not provided in detail by the present disclosure; or another branch can be arranged to detect the maximum value of the VBAT voltage, and the present application is not limited to the specific details herein. That is, in this case, the reference voltage VREF corresponds to the maximum value of the voltage VBAT in FIG. 2. In addition, a full-scale range of the first analog-to-digital converter can be switched accordingly to perform analog-to-digital conversion for different needs. Registers, switches, and other modules can also be arranged before or after the digital-to-analog converter to obtain the reference voltage VREF through corresponding modifications. After obtaining the reference voltage VREF, based on the principle of calculating the internal resistance of the battery unit BAT, the detection of the internal resistance of the battery unit BAT can be realized by controlling the on and off states of the first to fifth switches through the logic control circuit.

Furthermore, the reference voltage VREF can be the average value of the voltage VBAT across the battery unit. For example, FIG. 4 shows another embodiment of a reference voltage generation circuit provided according to the present disclosure. In this embodiment, the reference voltage generation circuit 30 includes a second analog-to-digital converter and a digital-to-analog converter; an input terminal of the second analog-to-digital converter is coupled to the third port VBAT; specifically, when the logic control circuit controls the first switch SW1 to operate at a certain frequency, the second analog-to-digital converter can perform analog-to-digital conversion on the voltage at the third port in at least one consecutive switching cycle and calculate the average value to output a third digital signal, or the second analog-to-digital converter can also output the third digital signal every time when a timing reaches a predetermined timing period, which can be set according to actual applications, wherein the second analog-to-digital converter performs analog-to-digital conversion on the voltage at the third port within the predetermined timing period and calculates the average value to output the third digital signal; the digital-to-analog converter converts the third digital signal into the reference voltage VREF. In some other embodiments according to the present disclosure, the reference voltage VREF can also be obtained by limiting the number of sampling conversions performed by the first analog-to-digital converter. In addition, registers, switches, and other modules can be arranged before or after the digital-to-analog converter, i.e., corresponding modifications can be made to this embodiment to obtain the reference voltage VREF. After obtaining the reference voltage VREF, similarly, based on the principle of calculating the internal resistance of the battery unit BAT, the detection of the internal resistance of the battery unit BAT can be realized by controlling the on and off states of the first to fifth switches through the logic control circuit.

It should be noted that the circuit schematic diagrams in FIG. 1, FIG. 3, and FIG. 4 are just some embodiments of this document, and the present disclosure is not limited thereto. Corresponding modifications to achieve same functions are also within the scope of the present application.

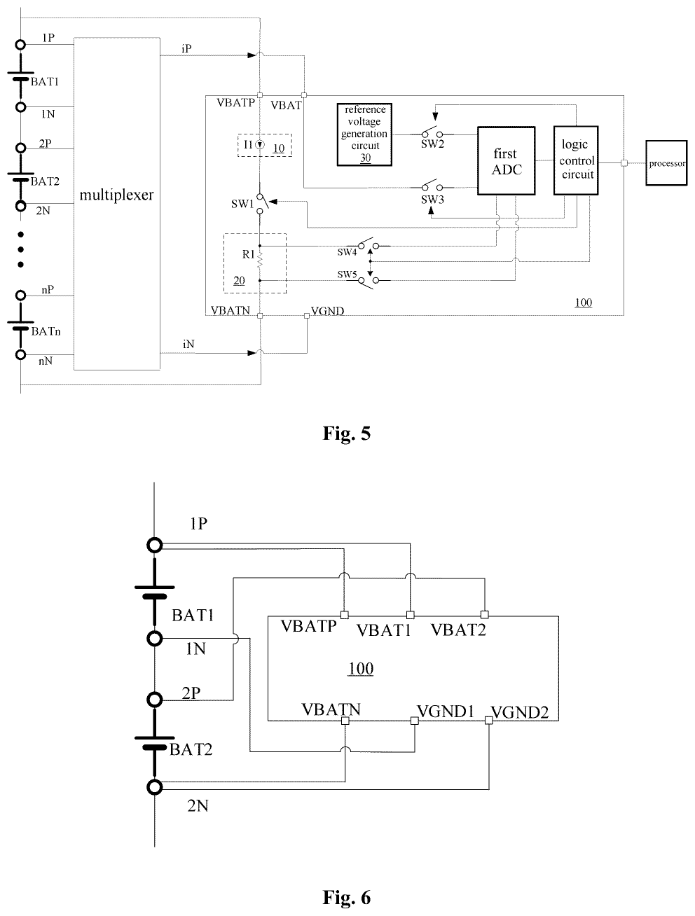

By taking N equal to 1 as an example, the principle of the detection circuit for detecting the internal resistance of the battery unit BAT is described as above. Of course, N can also take a value greater than 1. FIG. 5 shows another embodiment of the detection circuit for detecting the internal resistance of the battery unit provided according to the present disclosure. In this embodiment, N takes a value greater than 1, i.e., the battery unit BAT contains more than one sub-batteries (i.e., sub-batteries BAT1, BAT2 . . . . BATn). In this embodiment, the detection circuit further includes a multiplexer, which is used to select and couple a positive terminal of the i-th sub-battery with the third port VBAT in a time-sharing manner, and to couple a negative terminal of the i-th sub-battery with the fourth port VGND, where 1≤i≤N. That is, through the multiplexer, the detection circuit is shared by the N sub-batteries to achieve the detection of the internal resistance of each sub-battery. In one embodiment of this document, the operation of the multiplexer can be controlled by the logic control circuit.

Furthermore, to ensure the accuracy of disturbance voltage measurement, the voltage across the sub-battery coupled between the third port and the fourth port can be obtained using a Kelvin connection approach.

Furthermore, as shown in FIG. 1 and FIG. 3 to FIG. 5, components of the detection circuit for detecting the internal resistance of the battery unit, except for the processor, can be integrated into a single chip 100, and in this case, the logic control circuit can achieve information exchange with the processor through another port. Of course, in some other embodiments, the processor can also be integrated inside the chip 100. In addition, when the multiplexer is arranged, it can also be integrated inside the chip 100. Specific integration manners can be used according to actual applications.

Furthermore, when the battery unit BAT contains more than two sub-batteries (i.e., N is greater than 1), here, taking N equal to 2 as an example, as shown in FIG. 6, the detection circuit is further equipped with a fifth port VBAT2 and a sixth port VGND2, a positive terminal of the first sub-battery BAT1 is coupled to the third port, and a negative terminal of the first sub-battery BAT1 is coupled to the fourth port; a positive terminal of the second sub-battery BAT2 is coupled to the fifth port, and a negative terminal of the second sub-battery BAT2 is coupled to the sixth port. The circuits coupled to the fifth port and the sixth port can provide same functions as the circuits coupled to the third port and the fourth port, which will not be repeatedly described in detail hereto. In this way, the measurement of the voltage disturbance on the first sub-battery BAT1 can be realized through the third port and the fourth port; the measurement of the voltage disturbance on the second sub-battery BAT2 can be realized through the fifth port and the sixth port, thereby achieving the detection of the internal resistances of the corresponding sub-batteries. When N takes other values, a corresponding number of ports can also be arranged to simultaneously achieve the detection of the internal resistances of these N sub-batteries.

Furthermore, when the battery unit BAT contains multiple sub-batteries (e.g., N is greater than 2), as shown in FIG. 5, a multiplexer can be used to perform time-share multiplexing operation on the third to sixth ports to achieve the detection of the internal resistances of two sub-batteries simultaneously.

In addition, a battery pack can be finally formed by K serially-connected battery units BAT, which supply power to electronic devices, where K is a natural number greater than or equal to 1.

In summary, the detection circuit and the method for detecting the internal resistance of the battery unit provided by the present disclosure, controls the operating frequency of the first switch with the logic control circuit, so that a disturbance current at a certain frequency occurs in the battery unit, thereby causing a certain disturbance on the voltage of the battery unit. The disturbance amount of the voltage (or the difference between the voltage at the third port and the reference voltage) is converted into the first digital signal by the first analog-to-digital converter, and the internal resistance of the corresponding sub-battery is detected based on the first digital signal and the discharge current. According to the present disclosure, by sending the difference between the voltage at the third port VBAT and the reference voltage VREF to the first analog-to-digital converter for conversion, compared to a solution which directly sends the voltage VBAT at the third port to the first analog-to-digital converter for conversion, the voltage range to be quantified by the first analog-to-digital converter is smaller, which can improve resolution, reduce quantization error, and enhance detection accuracy. Moreover, this approach avoids the use of a DC-blocking filter capacitor, saving space and facilitating integration and miniaturization.

Furthermore, a current sampling circuit can be arranged to sample the magnitude of the discharge current, and the current sampling signal is converted into the second digital signal by the first analog-to-digital converter. Based on the first digital signal and the second digital signal, the internal resistance of the corresponding sub-battery is detected. With the above setup, since both the first digital signal and the second digital signal are converted by the first analog-to-digital converter, gain errors caused by different analog-to-digital converters can be avoided, improving the accuracy of battery internal resistance detection. Moreover, under the same detection accuracy, the discharge current can be set to a reduced magnitude through the solution provided according to the present disclosure, thereby reducing the system's power consumption.

Furthermore, the reference voltage according to the present disclosure can be converted by a digital-to-analog converter, where the digital signal can be a digital signal output by the logic control circuit, or a digital signal converted by the first analog-to-digital converter from a maximum value of the voltage of the battery. The reference voltage can also be the average value of the voltage of the battery. That is, the magnitude of the reference voltage according to the present disclosure can be adjusted according to the corresponding digital signal, enhancing flexibility.

Finally, it should be noted that: obviously, the above embodiments are merely examples for clearly illustrating the present disclosure and are not limitations on the implementation methods. For those skilled in the art, other different forms of changes or variations can be made based on the above description. It is not necessary to exhaust all the implementation methods here. Obvious changes or variations derived from this are still within the protection scope of the present disclosure.

What is claimed is:

1. A detection circuit for detecting an internal resistance of a battery unit, wherein the battery unit comprises at least one sub-battery connected in series, where N represents a quantity of the at least one sub-battery and is a natural number greater than or equal to 1; wherein the detection circuit comprises:
first to fourth ports, wherein a positive terminal of the battery unit is coupled to the first port, and a negative terminal of the battery unit is coupled to the second port, the third port is coupled to a positive terminal of one of the at least one sub-battery, and the fourth port is coupled to a negative terminal of the one of the at least one sub-battery;
a discharge current generation circuit and a first switch, wherein the discharge current generation circuit and the first switch are serially arranged in a branch between the first port and the second port, the discharge current generation circuit is used to generate a discharge current, and by controlling an operating frequency of the first switch, a current disturbance occurs in the battery unit;
a first analog-to-digital converter, which, based on the current disturbance, converts a difference between a voltage at the third port and a reference voltage into a first digital signal, the reference voltage being generated by a reference voltage generation circuit;
a logic control circuit, wherein the logic control circuit is configured to control the operating frequency of the first switch, and obtain an internal resistance of the sub-battery coupled between the third port and the fourth port in accordance with the first digital signal, and the discharge current or a second digital signal converted from a current sampling signal of the discharge current; or, the logic control circuit is configured to send the first digital signal, and the discharge current signal or the second digital signal converted from the current sampling signal of the discharge current, to a processor which is configured to process the signals to obtain the internal resistance of the sub-battery coupled between the third port and the fourth port.

2. The detection circuit according to claim 1, further comprising a current sampling circuit, configured to sample the discharge current to obtain the current sampling signal, and the first analog-to-digital converter is further used to convert the current sampling signal into the second digital signal.

3. The detection circuit according to claim 1, wherein the reference voltage generation circuit is a digital-to-analog converter, which is used to convert a received digital signal into the reference voltage.

4. The detection circuit according to claim 3, wherein the received digital signal is either a digital signal output by the logic control circuit, or a digital signal which is converted by the first analog-to-digital converter from a maximum voltage detected at the third port when the first switch is operated in off state.

5. The detection circuit according to claim 1, wherein when the logic control circuit controls the first switch to operate at a predetermined frequency, the reference voltage is an average value of a voltage at the third port.

6. The detection circuit according to claim 5, wherein the reference voltage generation circuit comprises a second analog-to-digital converter and a digital-to-analog converter; an input terminal of the second analog-to-digital converter is coupled to the third port,
wherein when the logic control circuit controls the first switch to operate at the predetermined frequency:
the second analog-to-digital converter performs analog-to-digital conversion and averaging operation on the voltage at the third port in at least one consecutive switching cycle and then outputs a third digital signal; or
the second analog-to-digital converter outputs a third digital signal every time when a timing reaches a predetermined timing period, wherein the second analog-to-digital converter performs analog-to-digital conversion and averaging operation on the voltage at the third port within the predetermined timing period and then outputs the third digital signal; and
the digital-to-analog converter is configured to convert the third digital signal into the reference voltage.

7. The detection circuit according to claim 1, further comprising a second switch and a third switch,
wherein the second switch is coupled in a branch between the reference voltage generation circuit and the first analog-to-digital converter; the third switch is coupled in a branch between the third port and the first analog-to-digital converter; the logic control circuit is configured to control on and off states of the second switch and the third switch;
wherein when the second switch and the third switch are operated in on state, the first analog-to-digital converter converts the difference between the voltage at the third port and the reference voltage into the first digital signal.

8. The detection circuit according to claim 2, wherein:
the current sampling circuit is a resistor, which is serially connected in a branch where the discharge current generation circuit is located; the current sampling signal is obtained in accordance with a voltage across the resistor;
the detection circuit further comprises a fourth switch and a fifth switch; the fourth switch is coupled in a branch between a first end of the resistor and the first analog-to-digital converter;
the fifth switch is coupled in a branch between a second end of the resistor and the first analog-to-digital converter; the logic control circuit is configured to control on and off states of the fourth switch and the fifth switch;
when the fourth switch and the fifth switch are operated in on state, the first analog-to-digital converter converts the current sampling signal into the second digital signal.

9. The detection circuit according to claim 1, wherein,
when N is greater than 1, the detection circuit further comprises a multiplexer, which is coupled to positive and negative terminals of the N sub-batteries; the multiplexer is used to select and couple a positive terminal of an i-th sub-battery of the N sub-batteries with the third port in a time-sharing manner, and to couple a negative terminal of the i-th sub-battery with the fourth port, where 1≤i≤N.

10. The detection circuit according to claim 1, wherein the voltage across the sub-battery that is coupled between the third port and the fourth port is obtained using a Kelvin connection approach.

11. The detection circuit according to claim 1, wherein the detection circuit is integrated inside a single chip; or, components of the detection circuit, except for the processor, is integrated inside a single chip.

12. A method for detecting an internal resistance of a battery unit, wherein the battery unit comprises at least one sub-battery connected in series, where N represents a quantity of the at least one sub-battery and is a natural number greater than or equal to 1; wherein the method comprises:
arranging a discharge current generation circuit and a first switch in series in a branch between a positive terminal and a negative terminal of the battery unit;
controlling an operating frequency of the first switch, to allow a current disturbance to occur in the battery unit;
coupling a positive terminal of one of the at least one sub-battery to a third port, and coupling a fourth port to a negative terminal of the one of the at least one sub-battery; based on the current disturbance, converting a difference between a voltage at the third port and a reference voltage into a first digital signal through a first analog-to-digital converter;
in accordance with the first digital signal, and the discharge current or a second digital signal converted from a current sampling signal of the discharge current, obtaining an internal resistance of the sub-battery coupled between the third port and the fourth port; or, sending the first digital signal, and the discharge current signal or the second digital signal converted from the current sampling signal of the discharge current, to a processor which is configured to process the signals to obtain the internal resistance of the sub-battery coupled between the third port and the fourth port.

13. The method according to claim 12, wherein
the current sampling signal is obtained by sampling the discharge current, and is converted into the second digital signal by the first analog-to-digital converter.

14. The method according to claim 12, wherein the reference voltage is obtained by conversion through a digital-to-analog converter, which is used to convert a received digital signal into the reference voltage.

15. The method according to claim 14, wherein the received digital signal is either a digital signal output by the logic control circuit, or a digital signal converted by the first analog-to-digital converter from a maximum voltage at the third port when the first switch is operated in off state.

16. The method according to claim 12, wherein when the logic control circuit controls the first switch to operate at a predetermined frequency, the reference voltage is an average value of a voltage at the third port.

17. The method according to claim 12, wherein when N is greater than 1, positive and negative terminals of the N sub-batteries are coupled to a multiplexer; the multiplexer is used to select and couple a positive terminal of an i-th sub-battery of the N sub-batteries with the third port in a time-sharing manner, and to couple a negative terminal of the i-th sub-battery with the fourth port, where 1≤i≤N.

18. The method according to claim 12, wherein the voltage across the sub-battery that is coupled between the third port and the fourth port is obtained using a Kelvin connection approach.
